(19) United States
(12) Patent Application Publication
(10) Pub. No.: US 2017/0324025 A1
(43) Pub. Date: Nov. 9, 2017

(54) DATA STORAGE DEVICES AND METHODS FOR MANUFACTURING THE SAME

(71) Applicants: KILHO LEE, Busan (KR); Kiseok SUH, Hwaseong-si (KR); Yoonsung HAN, Seoul (KR); GWANHYEOB KOH, Seoul (KR); YOONJONG SONG, Seoul (KR)

(72) Inventors: KILHO LEE, Busan (KR); Kiseok SUH, Hwaseong-si (KR); Yoonsung HAN, Seoul (KR); GWANHYEOB KOH, Seoul (KR); YOONJONG SONG, Seoul (KR)

(21) Appl. No.: 15/436,757

(22) Filed: Feb. 17, 2017

(30) Foreign Application Priority Data
May 3, 2016 (KR) 10-2016-0054792

(51) Int. Cl. H01L 43/02; H01L 43/12

(52) U.S. Cl. CPC H01L 43/02; H01L 43/12

(57) ABSTRACT

A data storage device and a method for manufacturing the data storage device provide a data storage device having a superior reliability and easy fabrication. The data storage device comprises a substrate including cell and peripheral circuit regions, a first conductive line on the peripheral circuit region, a peripheral contact plug between the substrate and the first conductive line, the peripheral contact plug being in contact with the first conductive line, a second conductive line on the cell region, a plurality of data storage structures between the substrate and the second conductive line, and a wiring structure between the substrate and each of the data storage structures and between the substrate and the peripheral contact plug. The first conductive line includes a bottom surface having a position from the substrate that is lower than a position of a bottom surface of the second conductive line.

### CROSS-REFERENCE TO RELATED APPLICATIONS

This U.S. nonprovisional patent application claims priority under 35 U.S.C. §119 of Korean Patent Application 10-2016-0054792 filed on May 3, 2016, the entire contents of which are hereby incorporated by reference.

### BACKGROUND

The present inventive concept relates to a semiconductor device and a method for manufacturing the semiconductor device and, more particularly, to a data storage device and a method for manufacturing the data storage device.

Semiconductor devices have an important role in the electronic industry because of the small size, multi-function and/or low fabrication cost of the semiconductor devices. Data storage semiconductor devices can store logic data. The semiconductor devices are increasingly integrated as the electronics industry has developed. The data storage devices have also been increasingly integrated and are being fabricated to have reduced line widths.

Additionally, high reliability has been demanded with the high integration of the data storage devices. However, the high integration may deteriorate the reliability of the data storage devices. Therefore, research is being conducted to enhance the reliability of the data storage devices.

### SUMMARY

Embodiments disclosed herein provide a data storage device and a method for manufacturing the same in which the data storage device can be easily fabricated.

Embodiments disclosed herein provide a data storage device and a method for manufacturing the same in which the data storage device has a superior reliability.

According to exemplary embodiments disclosed herein, a data storage device may comprise: a substrate including a cell region and a peripheral circuit region; a first conductive line on the peripheral circuit region of the substrate; a peripheral contact plug between the substrate and the first conductive line, the peripheral contact plug being in contact with the first conductive line; a second conductive line on the cell region of the substrate; a plurality of data storage structures between the substrate and the second conductive line, the plurality of data storage structures connecting to the second conductive line; and a wiring structure between the substrate and each of the data storage structures and between the substrate and the peripheral contact plug. The first conductive line may include a bottom surface having a position from the substrate that is lower than a position of a bottom surface of the second conductive line.

According to exemplary embodiments disclosed herein, a method for manufacturing a data storage device may comprise: providing a substrate including a cell region and a peripheral circuit region; forming a plurality of data storage structures on the cell region of the substrate; forming a mold layer that covers the data storage structures and extends onto the peripheral circuit region on the substrate; forming a mask layer that covers the cell region and the peripheral circuit region on the mold layer; forming a first opening in the mask layer, the first opening exposing the mold layer formed on the peripheral circuit region; etching the mold layer using the mask layer having the first opening as an etch mask to form a preliminary trench in the mold layer formed on the peripheral circuit region; forming a second opening in the mask layer, the second opening exposing the mold layer formed on the cell region; and etching the mold layer using the mask layer having the first and second openings as an etch mask to form a first trench extending from the preliminary trench toward the substrate and a second trench exposing the data storage structures.

According to exemplary embodiments disclosed herein, a data storage device may include a substrate comprising a cell region and a peripheral circuit region; a mold layer on the cell region and the peripheral circuit region; a first conductive line on the mold layer in the cell region in which a bottom surface of the first conductive line is at a first height above the substrate; a plurality of data storage structures in contact with the first conductive line in which the plurality of data storage structures are disposed between the substrate and the first conductive line; a second conductive line on the mold layer in the peripheral circuit region in which a bottom surface of the second conductive line is at a second height above the substrate and in which the second height is less that the first height; and a peripheral contact plug in contact with the second conductive line and being disposed between the substrate and the second conductive line.

According to exemplary embodiments disclosed herein, a method to form a data storage device may include: providing a substrate comprising a cell region and a peripheral circuit region; forming a mold layer on the cell region and the peripheral circuit region; forming a first conductive line on the mold layer in the cell region in which a bottom surface of the first conductive line is at a first height above the substrate; forming a plurality of data storage structures in contact with the first conductive line in which the plurality of data storage structures are disposed between the substrate and the first conductive line; forming a second conductive line on the mold layer in the peripheral circuit region in which a bottom surface of the second conductive line are at a second height above the substrate and in which the second height is less that the first height; and forming a peripheral contact plug in contact with the second conductive line and being disposed between the substrate and the second conductive line.

### BRIEF DESCRIPTION OF THE DRAWINGS

FIG. 1 depicts a plan view illustrating a data storage device according to exemplary embodiments of the present inventive concept.

FIG. 2 depicts a plan view illustrating an example of a second conductive line of FIG. 1.

FIG. 3 depicts cross-sectional views taken along lines A-A′, B-B′, C-C′ and D-D′ of FIG. 1.

FIG. 4 depicts a cross-sectional view taken along line E-E′ of FIG. 2.

FIG. 5 depicts an embodiment of a method to manufacture a data storage device according to exemplary embodiments disclosed herein.

FIGS. 6A to 11A depict cross-sectional views, corresponding to lines A-A′, B-B′, C-C′ and D-D′ of FIG. 1, and illustrate a method for manufacturing a data storage device according to exemplary embodiments disclosed herein.

FIGS. 6B to 11B depict cross-sectional views, corresponding to line E-E′ of FIG. 2, and illustrate a method for manufacturing a data storage device according to exemplary embodiments disclosed herein.

FIG. 12 depicts a cross-sectional view illustrating an example of the data storage section according to exemplary embodiments disclosed herein.

FIG. 13 depicts a cross-sectional view illustrating another example of the data storage section according to exemplary embodiments disclosed herein.

FIG. 14 depicts a unit memory cell of a data storage device according to exemplary embodiments disclosed herein.

FIG. 15 depicts an electronic device that comprises one or more integrated circuits (chips) comprising a semiconductor device that includes a data storage device according to embodiments disclosed herein.

### DETAILED DESCRIPTION OF EMBODIMENTS

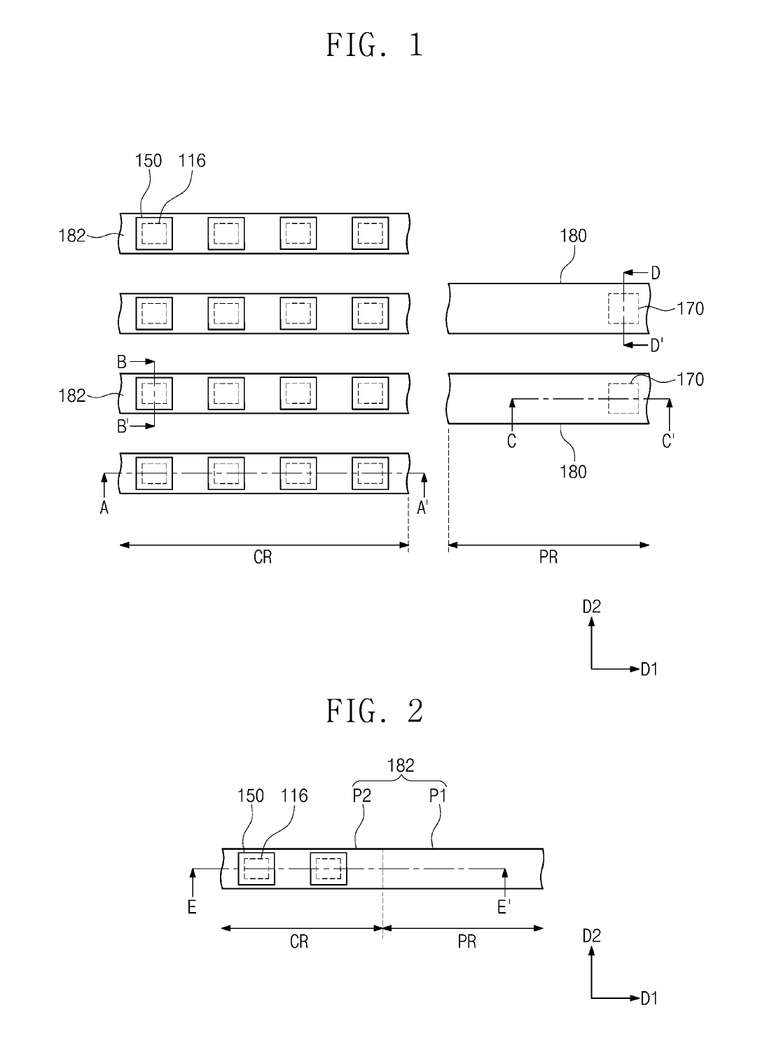

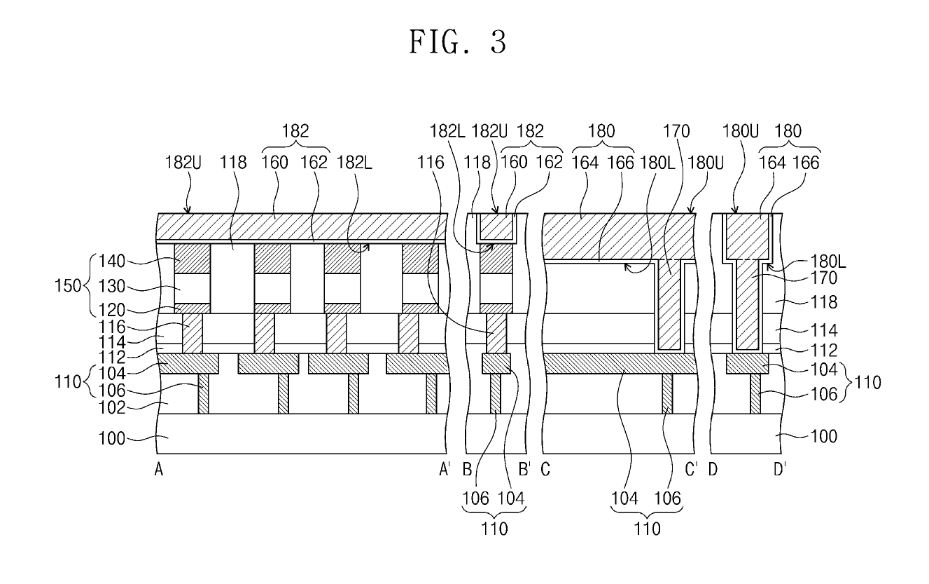

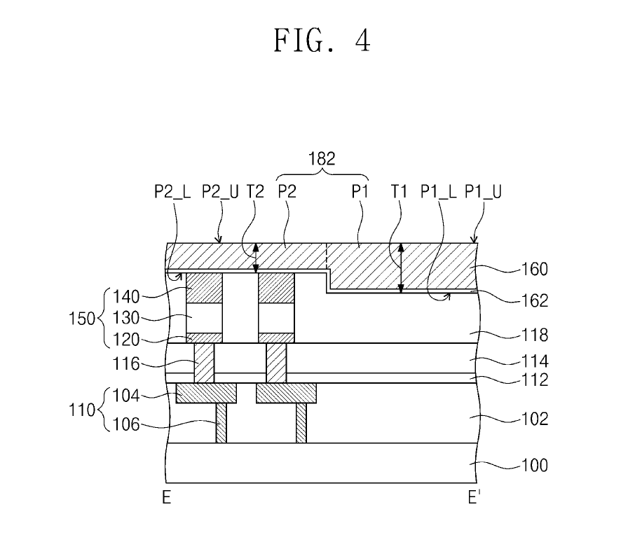

FIG. 1 depicts a plan view illustrating a data storage device according to exemplary embodiments disclosed herein. FIG. 2 depicts a plan view illustrating an example of a second conductive line 182 of FIG. 1. FIG. 3 depicts cross-sectional views taken along lines A-A′, B-B′, C-C′ and D-D′ of FIG. 1. FIG. 4 depicts a cross-sectional view taken along line E-E′ of FIG. 2.

Referring to FIGS. 1 and 3, a substrate 100 may be provided to include a cell region CR and a peripheral circuit region PR. The cell region CR may be a portion of the substrate 10 in which memory cells are provided, and the peripheral circuit region PR may be a portion of the substrate 10 in which peripheral circuits are provided. The substrate 100 may be a semiconductor substrate that includes silicon, silicon on insulator (SOI), silicon-germanium (SiGe), germanium (Ge), gallium-arsenic (GaAs), etc.

A first interlayer dielectric layer 102 may be disposed on the substrate 100. The first interlayer dielectric layer 102 may cover selection devices (not shown) that are provided on the substrate 100. The selection devices may include field effect transistors or diodes. The first interlayer dielectric layer 102 may include an oxide, a nitride, and/or an oxynitride. The first interlayer dielectric layer 102 may include a wiring structure 110 that is provided in the first interlayer dielectric layer 102. The wiring structure 110 may include lines 104 that are spaced apart from the substrate 100 and contacts 106 that are connected to the lines 104. The lines 104 may be electrically connected to the substrate 100 through the contacts 106. The wiring structure 110 may further include lower lines (not shown) and lower contacts (not shown) that are connected to the lower lines. The lower lines may be disposed between the substrate 100 and the contacts 106, and the lower contacts may be disposed between the substrate 100 and the lower lines. The lines 104 may be connected to the lower lines through the contacts 106, and the lower lines may be electrically connected to the substrate 100 through the lower contacts. The lines 104 and the contacts 106 may include a metallic material. For example, the lines 104 and the contacts 106 may include copper (Cu). In some embodiments, the lines 104 may include top surfaces that are substantially coplanar with a top surface of the first interlayer dielectric layer 102.

A second interlayer dielectric layer 114 may be provided on the first interlayer dielectric layer 102. An intermediate layer 112 may be interposed between the first interlayer dielectric layer 102 and the second interlayer dielectric layer 114. The second interlayer dielectric layer 114 and the intermediate layer 112 may cover an entire surface of the substrate 100 and further cover the top surfaces of the lines 104. The second interlayer dielectric layer 114 may include an oxide, a nitride, and/or an oxynitride. The intermediate layer 112 may include a nitride. The intermediate layer 112 may include, for example, carbon containing silicon nitride.

A plurality of cell contact plugs 116 may be provided that penetrate the second interlayer dielectric layer 114 and the intermediate layer 112 on the cell region CR of the substrate 100. The cell contact plugs 116 may be configured to penetrate the second interlayer dielectric layer 114 and the intermediate layer 112 and thus be connected to the lines 104 of the wiring structure 110. Each of the cell contact plugs 116 may be connected to a corresponding one of the lines 104. Each of the cell contact plugs 116 may be in direct contact with a top surface of the corresponding one of the lines 104. The each of the cell contact plugs 116 may be electrically connected to a terminal of a corresponding one of the selection devices through a corresponding one of the lines 104. The cell contact plugs 116 may include a doped semiconductor material (e.g., doped silicon), a metal (e.g., tungsten, titanium, and/or tantalum), a conductive metal nitride (e.g., titanium nitride, tantalum nitride, and/or tungsten nitride), and/or a metal-semiconductor compound (e.g., metal silicide). In some embodiments, the cell contact plugs 116 may include top surfaces that are substantially coplanar with a top surface of the second interlayer dielectric layer 114.

A plurality of data storage structures 150 may be provided on the second interlayer dielectric layer 114. The data storage structures 150 may be provided on the cell region CR of the substrate 100 and, as viewed in the plan view of FIG. 1, may be two-dimensionally arranged along a first direction D1 and a second direction D2 that crosses the first direction D1. The second direction D2 is perpendicular to the first direction D1. The data storage structures 150 may be respectively connected to the cell contact plugs 116. Each of the data storage structures 150 may include a data storage section 130, a bottom electrode 120 that is between the data storage section 130 and a corresponding cell contact plug 116, and a top electrode 140 that is spaced apart from a bottom electrode 120 with the data storage section 130 interposed between the top electrode 140 and the bottom electrode 120. In some embodiments, the bottom electrode 120 may be in direct contact with a corresponding cell contact plug 116. The bottom electrode 120 and the top electrode 140 may include a conductive material. For example, the bottom electrode 120 and the top electrode 140 may include a conductive metal nitride (e.g., titanium nitride or tantalum nitride). The data storage section 130 will be explained in detail below.

A mold layer 118 may be provided on the second interlayer dielectric layer 114 and cover the data storage structures 150. The mold layer 118 may be provided on the cell region CR of the substrate 100 and cover sidewalls of the data storage structures 150. The mold layer 118 may extend onto the peripheral circuit region PR of the substrate 100 and be in contact with the second interlayer dielectric layer 114. The mold layer 118 may include an oxide, a nitride, and/or an oxynitride.

A first conductive line 180 may be provided in the mold layer 118 on the peripheral circuit region PR. In some embodiments, the first conductive line 180 may extend in substantially the first direction D1, but the present inventive concept is so limited and in some embodiments the first conductive line 180 may extend in a direction that is different from the first direction D1. A peripheral contact plug 170 may be provided between the first conductive line 180 and the substrate 100. The peripheral contact plug 170 may be provided between the first conductive line 180 and the wiring structure 110, and may be in contact with the first conductive line 180. The peripheral contact plug 170 may be configured to penetrate the mold layer 118, the second interlayer dielectric layer 114, and the intermediate layer 112 and thus be connected to a corresponding one of the lines 104 of the wiring structure 110. The peripheral contact plug 170 may be electrically connected to a terminal of a corresponding one of the selection devices (not shown) through the corresponding one of the lines 104. The first conductive line 180 may include a top surface 180U that is substantially coplanar with a top surface of the mold layer 118. The first conductive line 180 may include a first line pattern 164 and a first barrier pattern 166 that extends along sidewalls and a bottom surface of the first line pattern 164. An extending direction of the first line pattern 164 may be substantially the same as an extending direction of the first conductive line 180. The peripheral contact plug 170 may be in contact with the first line pattern 164 without an interface between the peripheral contact plug 170 and the first line pattern 164. For example, the peripheral contact plug 170 may extend from the bottom surface of the first line pattern 164 and may be integrally combined with the first line pattern 164 to form a single unitary body. The first barrier pattern 166 may extend from the bottom surface of the first line pattern 164 toward sidewalls and a bottom surface of the peripheral contact plug 170. The first barrier pattern 166 may be interposed between the first line pattern 164 and the mold layer 118, and between the peripheral contact plug 170 and the mold layer 118. The first barrier pattern 166 may extend between the peripheral contact plug 170 and the second interlayer dielectric layer 114 and between the peripheral contact plug 170 and the intermediate layer 112. The first barrier pattern 166 may be interposed between the bottom surface of the peripheral contact plug 170 and a corresponding line 104 that is connected to the peripheral contact plug 170. The first barrier pattern 166 may be in direct contact with a top surface of the corresponding line 104 that is connected to the peripheral contact plug 170. The first line pattern 164 and the peripheral contact plug 170 may include the same material. The first line pattern 164 and the peripheral contact plug 170 may include a metallic material (e.g., copper (Cu)). The first barrier pattern 166 may include a conductive metal nitride.

A second conductive line 182 may be provided in the mold layer 118 on the cell region CR. A plurality of the second conductive line 182 may be provided, and the plurality of second conductive lines 182 may extend substantially in the first direction D1 and may be spaced apart from each other in the second direction D2. The second conductive line 182 may be commonly connected to the data storage structures 150 that are arranged in the first direction D1. In some embodiments, the second conductive line 182 may be commonly in contact with the top surfaces of the data storage structures 150 that are arranged in the first direction D1. The second conductive line 182 may include a top surface 182U that is substantially coplanar with the top surface of the mold layer 118. The second conductive line 182 may include a second line pattern 160 and a second barrier pattern 162 that extends along sidewalls and a bottom surface of the second line pattern 160. The second barrier pattern 162 may be interposed between the second line pattern 160 and the mold layer 118, and between the second line pattern 160 and each of the data storage structures 150. The second line pattern 160 may include the same material as used to form the first line pattern 164 and the peripheral contact plug 170. The second line pattern 160 may include a metallic material (e.g., copper (Cu)). The second barrier pattern 162 may include the same material as used to form the first barrier pattern 166. The second barrier pattern 162 may include a conductive metal nitride.

The first conductive line 180 may include a bottom surface 180L that has a position with respect to the substrate 100 that is lower than a position of a bottom surface 182L of the second conductive line 182 with respect to the substrate 100. That is, the first conductive line 180 may include a bottom surface 180L that has a height above the substrate 100 that is lower than a height above the substrate 100 of a bottom surface 182L of the second conductive line 182. The top surface 180U of the first conductive line 180 may be positioned at substantially the same height from the substrate 100 as the top surface 182U of the second conductive line 182. Each of the first and second conductive lines 180 and 182 may function as a bit line.

Referring to FIGS. 2 and 4, in some embodiments, at least one of the second conductive lines 182 may extend into the peripheral circuit region PR from the cell region CR. The second conductive line 182 may include a first part P1 on the peripheral circuit region PR and a second part P2 on the cell region CR. The second part P2 may be commonly connected to the data storage structures 150 that are arranged in the first direction DE A top surface P1_U of the first part P1 and a top surface P2_U of the second part P2 may be positioned at substantially the same height with respect to the substrate 100. The first part P1 may have a bottom surface P1_L that has a position with respect to the substrate 100 that is lower than a position of a bottom surface P2_L of the second part P2 with respect to the substrate 100. That is, the first part P1 may have a bottom surface P1_L that has a height above the substrate 100 that is lower than a height of a bottom surface P2_L of the second part P2 above the substrate 100. For example, the first part P1 may have a first thickness T1 that is greater than a second thickness T2 of the second part P2. The second line pattern 160 may have a thickness that is less in the cell region CR than in the peripheral circuit region PR. The bottom surface of the second line pattern 160 may have a stepped profile at an interface between the first and second parts P1 and P2. The second barrier pattern 162 may extend toward the peripheral circuit region PR from the cell region CR along the bottom surface of the second line pattern 160.

When the bottom surfaces 180L and 182L of the first and second conductive lines 180 and 182 are positioned at substantially the same height with respect to the substrate 100, an electrical connection between the first conductive line 180 and a corresponding line 104 may necessitate that the peripheral contact plug 170 should be formed to have a high aspect ratio or another contact (or pad) may be needed in addition to the peripheral contact plug 170.

According to the present inventive concept, the bottom surface 180L of the first conductive line 180 may be positioned to be lower than the bottom surface 182L of the second conductive line 182. That is, the bottom surface 180L of the first conductive line 180 may have a height above the substrate 100 that is lower than the bottom surface 182L of the second conductive line 182 above the substrate 100. It thus may be possible that the peripheral contact plug 170 may be formed to have a relatively low aspect ratio for the electrical connection between the first conductive line 180 and its corresponding line 104. In other words, it may be possible to easily form the peripheral contact plug 170 because the peripheral contact plug 170 has a relatively low aspect ratio. Furthermore, no additional contact (or pad) may be required for the electrical connection between the first conductive line 180 and its corresponding line 104. As a result, it may be advantageous to simplify the fabrication process of the data storage device and to prevent the occurrence of defects caused by the formation of the additional contact (or pad).

It may then be possible to easily fabricate the data storage device having superior reliability.

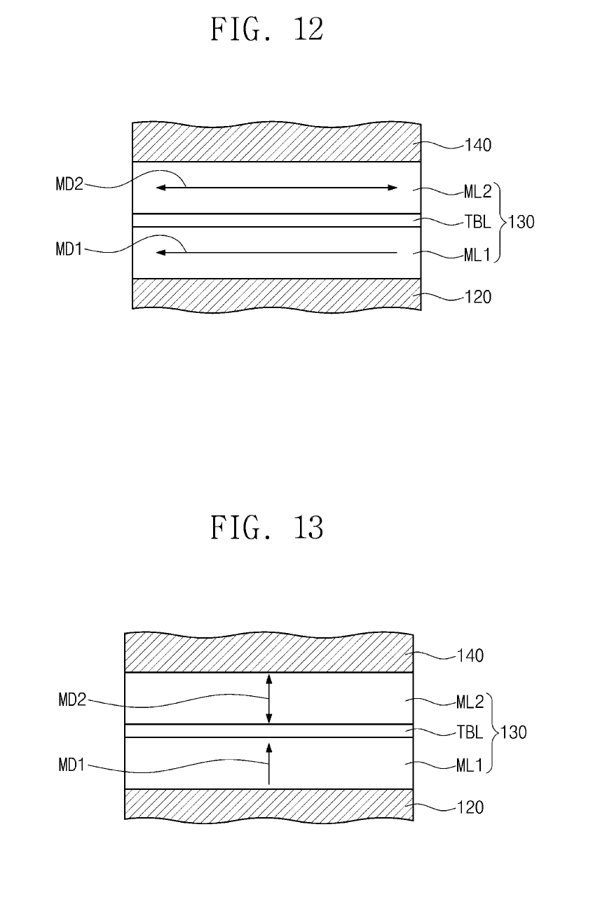

The data storage section 130 will be hereinafter discussed in detail with reference to FIGS. 12 and 13. FIG. 12 depicts a cross-sectional view illustrating an example of the data storage section 130 according to exemplary embodiments disclosed herein. FIG. 13 depicts a cross-sectional view illustrating another example of the data storage section 130 according to exemplary embodiments disclosed herein.

Referring to FIG. 12, the data storage section 130 may include a reference layer ML1, a free layer ML2, and a tunnel barrier TBL between the reference layer ML1 and the free layer ML2. The reference layer ML1 may have a unidirectionally fixed magnetization direction MD1, and the free layer ML2 may have a variable magnetization direction that may be changed to be parallel or antiparallel to the magnetization direction MD1 of the reference layer ML1. The magnetization directions MD1 and MD2 of the reference and free layers ML1 and ML2 may be parallel or substantially parallel to an interface between the tunnel barrier TBL and the free layer ML2. FIG. 12 may depict that the free layer ML2 is interposed between the tunnel barrier TBL and the top electrode 140, but the present inventive concept is not limited thereto. That is, unlike the particular embodiment depicted in FIG. 12, the free layer ML2 may be interposed between the tunnel barrier TBL and the bottom electrode 120. The reference layer ML1, the tunnel barrier TBL, and the free layer ML2 may form a magnetic tunnel junction. In the case that the magnetization directions MD1 and MD2 of the reference and free layers ML1 and ML2 are parallel to the interface, each of the reference and free layers ML1 and ML2 may include a ferromagnetic material. The reference layer ML1 may further include an antiferromagnetic material to fix a magnetization direction of the ferromagnetic material in the reference layer ML1.

Referring to FIG. 13, the data storage section 130 may include a reference layer ML1, a free layer ML2, and a tunnel barrier TBL between the reference layer ML1 and the free layer ML2. The reference layer ML1 may have a unidirectionally fixed magnetization direction MD1, and the free layer ML2 may have a variable magnetization direction that may be changed to be parallel or antiparallel to the magnetization direction MD1 of the reference layer ML1. The magnetization directions MD1 and MD2 of the reference and free layers ML1 and ML2 may be vertical or substantially vertical to an interface between the tunnel barrier TBL and the free layer ML2. FIG. 13 may depict that the free layer ML2 is interposed between the tunnel barrier TBL and the top electrode 140, but the present inventive concept is not limited thereto. That is, unlike the particular embodiment depicted in FIG. 13, the free layer ML2 may be interposed between the tunnel barrier TBL and the bottom electrode 120. The reference layer ML1, the tunnel barrier TBL, and the free layer ML2 may form a magnetic tunnel junction. In the case that the magnetization directions MD1 and MD2 of the reference and free layers ML1 and ML2 are vertical to the interface, each of the reference and free layers ML1 and ML2 may include a perpendicular magnetic material (e.g., CoFeTb, CoFeGd, CoFeDy), a perpendicular magnetic material having an L10 structure, CoPt of a hexagonal close packed (HCP) lattice structure, and/or a perpendicular magnetic structure. The perpendicular magnetic material having the L10 structure may include FePt of an L10 structure, FePd of an L10 structure, CoPd of an L10 structure, and/or CoPt of an L10 structure. The perpendicular magnetic structure may include magnetic layers and non-magnetic layers that are alternately and repeatedly stacked. For example, the perpendicular magnetic structure may include at least one of (Co/Pt)n, (CoFe/Pt)n, (CoFe/Pd)n, (Co/Pd)n, (Co/Ni)n, (CoNi/Pt)n, (CoCr/Pt)n, and/or (CoCr/Pd)n (in which n is the number of stacked layers).

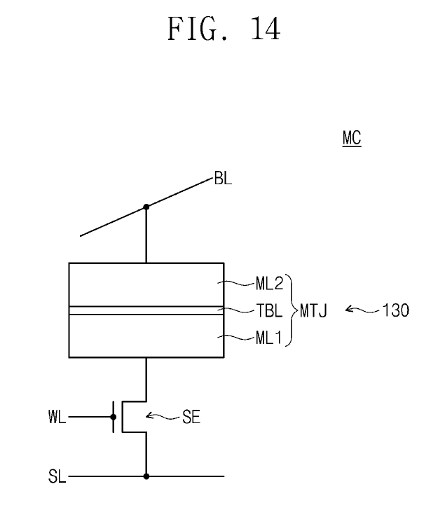

FIG. 14 depicts a unit memory cell of a data storage device 130 according to exemplary embodiments disclosed herein.

Referring to FIG. 14, each unit memory cell MC may include the data storage section 130 and a corresponding selection device SE. The data storage section 130 and the selection device SE may be electrically connected in series. The data storage section 130 may be connected between a bit line BL and the selection device SE. The selection device SE may be connected between the data storage section 130 and a source line SL, and a word line WL may be provided to control the selection device SE.

The data storage section 130 may include a magnetic tunnel junction MTJ having magnetic layers ML1 and ML2 that are spaced apart from each other and a tunnel barrier TBL between the magnetic layers ML1 and ML2. One of the magnetic layers ML1 and ML2 may be a reference layer having a magnetization direction that is fixed irrespective of an external magnetic field under a normal-use environment. The other one of the magnetic layers ML1 and ML2 may be free layer having a magnetization direction that is freely changed in response to an external magnetic field.

The magnetic tunnel junction MTJ may have an electrical resistance value that is much greater in a case in which the magnetization directions of the reference and free layers are antiparallel to each other than in a case in which the magnetization directions of the reference and free layers are parallel to each other. For example, the electrical resistance of the magnetic tunnel junction may be adjusted by changing the magnetization direction of the free layer. The data storage section 130 may then store data in the unit memory cell MC using the difference of the electrical resistance in accordance with the magnetization direction.

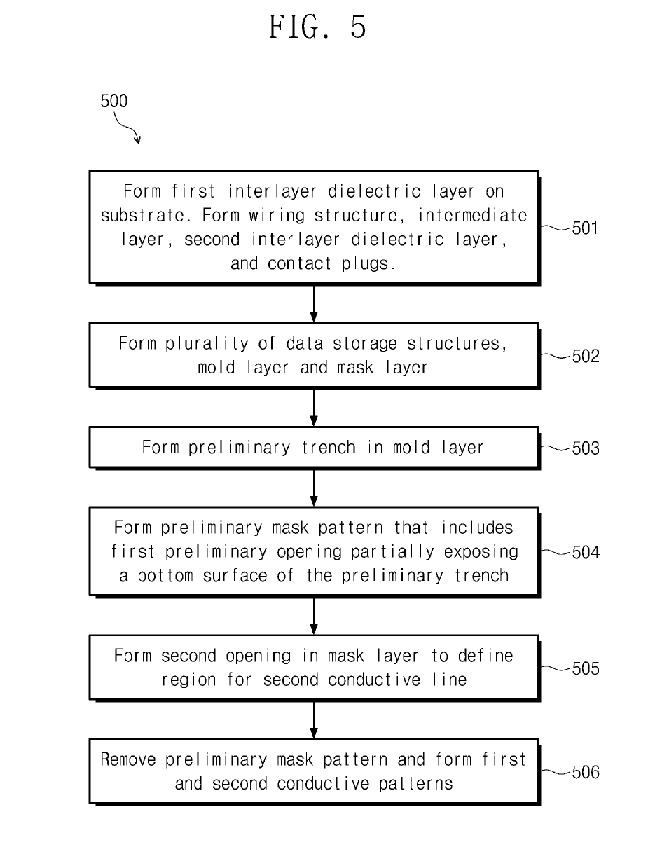

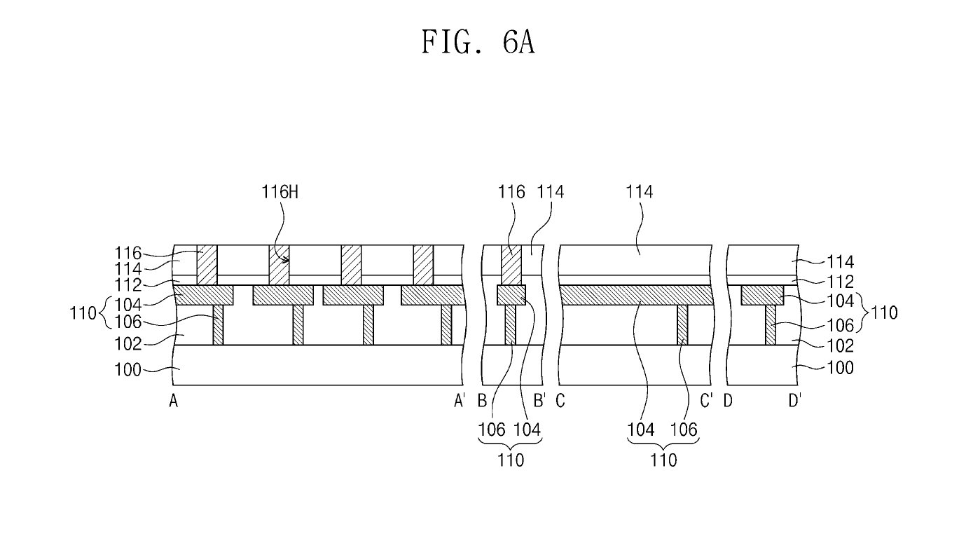

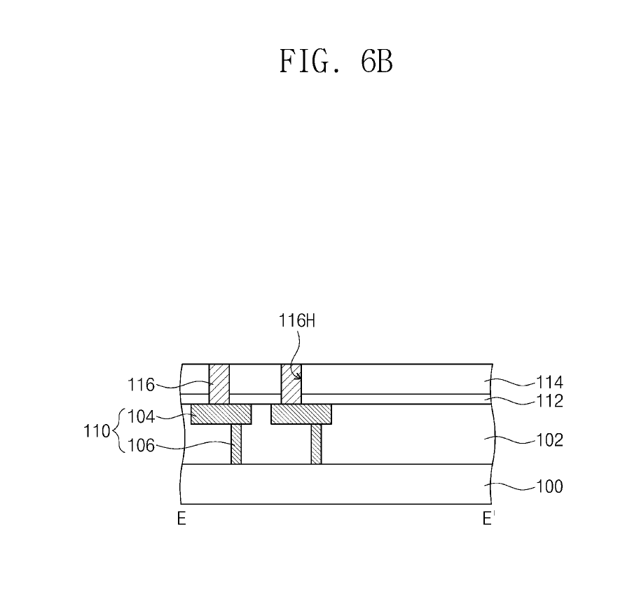

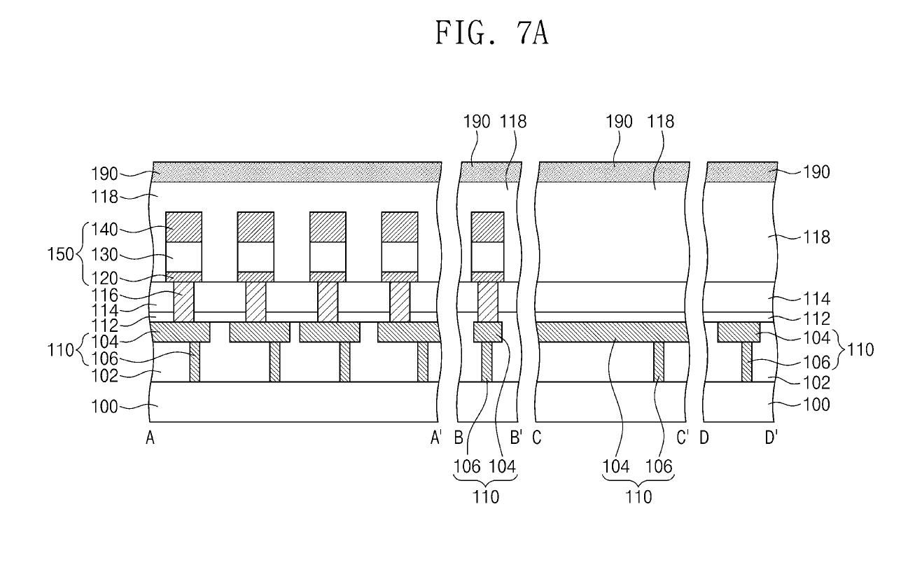

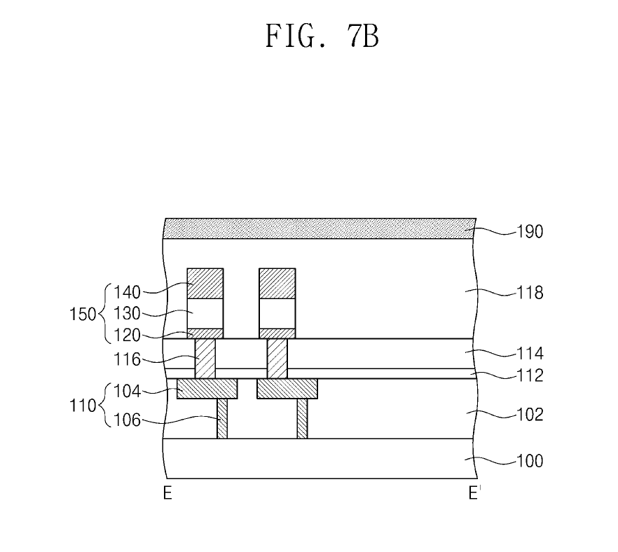

FIG. 5 depicts an embodiment of a method to manufacture a data storage device according to exemplary embodiments disclosed herein. FIGS. 6A to 11A depict cross-sectional views corresponding to lines A-A′, B-B′, C-C′ and D-D′ of FIG. 1 and illustrate a method for manufacturing a data storage device according to exemplary embodiments disclosed herein. FIGS. 6B to 11B depict cross-sectional views corresponding to line E-E′ of FIG. 2 and illustrate a method for manufacturing a data storage device according to exemplary embodiments disclosed herein.

Referring to FIGS. 6A and 6B, at 501 in FIG. 5 a first interlayer dielectric layer 102 may be formed on a substrate 100. The substrate 100 may be a semiconductor substrate including silicon, silicon on insulator (SDI), silicon-germanium (SiGe), germanium (Ge), gallium-arsenic (GaAs), etc. A plurality of selection devices (not shown) may be formed on the substrate 100, and a wiring structure 110 may be formed on and electrically connected to the substrate 100. In one embodiment, the selection devices may be field effect transistors. In an alternative embodiment, the selection devices may be diodes. The wiring structure 110 may include lines 104 that are spaced apart from the substrate 100 and contacts 106 that are connected to the lines 104. The lines 104 may be electrically connected to the substrate 100 through the contacts 106. At least one of the lines 104 may be electrically connected to a terminal of a corresponding one of the selection devices through a contact 106. The wiring structure 110 may further include lower lines (not shown) and lower contacts (not shown) that are connected to the lower lines. The lower lines may be disposed between the substrate 100 and the contacts 106, and the lower contacts may be disposed between the substrate 100 and the lower lines. The lines 104 may be connected to the lower lines through the contacts 106, and the lower lines may be electrically connected to the substrate 100 through the lower contacts. The lines 104 and the contacts 106 may include a metallic material. For example, the lines 104 and the contacts 106 may include copper (Cu). The first interlayer dielectric layer 102 may be formed to cover the selection devices and the wiring structure 110. The first interlayer dielectric layer 102 may be formed in a single layer or multiple layers that include an oxide, a nitride, and/or an oxynitride. In some embodiments, the lines 104 may have top surfaces that are substantially coplanar with a top surface of the first interlayer dielectric layer 102.

An intermediate layer 112 and a second interlayer dielectric layer 114 may be sequentially stacked on the first interlayer dielectric layer 102. The second interlayer dielectric layer 114 may include an oxide, a nitride, and/or an oxynitride, and the intermediate layer 112 may include a nitride. The intermediate layer 112 may include, for example, carbon containing silicon nitride.

A plurality of cell contact plugs 116 may be formed to penetrate the second interlayer dielectric layer 114 and the intermediate layer 112 on the cell region CR of the substrate 100. The formation of the cell contact plugs 116 may include forming cell contact holes 116H to penetrate the second interlayer dielectric layer 114 and the intermediate layer 112, and then forming the cell contact plugs 116 in the respective cell contact holes 116H. Each of the cell contact holes 116H may expose a top surface of a corresponding one of the lines 104. Each of the cell contact plugs 116 may be electrically connected to a terminal of a corresponding one of the selection devices through a corresponding one of the lines 104. The cell contact plugs 116 may include a doped semiconductor material (e.g., doped silicon), a metal (e.g., tungsten, titanium, and/or tantalum), a conductive metal nitride (e.g., titanium nitride, tantalum nitride, and/or tungsten nitride), and/or a metal-semiconductor compound (e.g., metal silicide). The cell contact plugs 116 may have top surfaces that are substantially coplanar with a top surface of the second interlayer dielectric layer 114.

Referring to FIGS. 7A and 7B, at 502 in FIG. 5 a plurality of data storage structures 150 may be formed on the cell region CR of the substrate 100. More specifically, a bottom electrode layer and a data storage layer may be sequentially formed on the second interlayer dielectric layer 114, and conductive mask patterns 140 may be formed on the data storage layer. As viewed in a plan view, the conductive mask patterns 140 may define regions where the data storage structures 150 are formed, such as depicted in FIG. 1. The data storage layer and the bottom electrode layer may be sequentially etched using each of the conductive mask patterns 140 as an etch mask to form a data storage section 130 and a bottom electrode 120. Each of the conductive mask patterns 140 may function as a top electrode 140. Each of the data storage structures 150 may include the top electrode 140, the data storage section 130, and the bottom electrode 120. The bottom and top electrodes 120 and 140 may include a conductive material. For example, the bottom and top electrodes 120 and 140 may include a conductive metal nitride (e.g., titanium nitride or tantalum nitride). As discussed with reference to FIGS. 12 and 13, the data storage section 130 may include the reference layer ML1, the tunnel barrier TBL, and the free layer ML2 that are sequentially stacked on the bottom electrode 120. In this case, the data storage layer may include a reference magnetic layer, a tunnel barrier layer, and a free magnetic layer that are sequentially stacked on the bottom electrode layer. The reference magnetic layer, the tunnel barrier layer, and the free magnetic layer may be sequentially etched using the conductive mask patterns 140 as an etch mask to form the reference layer ML1, the tunnel barrier TBL, and the free layer ML2.

A mold layer 118 may be formed on the second interlayer dielectric layer 114 and cover the data storage structures 150. The mold layer 118 may be provided on the cell region CR of the substrate 100 and cover sidewalls of the data storage structures 150, and may extend toward the peripheral circuit region PR of the substrate 100 and contact with the second interlayer dielectric layer 114. The mold layer 118 may include an oxide, a nitride, and/or an oxynitride. A mask layer 190 may be formed on the mold layer 118 and cover the cell region CR and the peripheral circuit region PR. The mask layer 190 may include a material having an etch selectivity with respect to the mold layer 118. For example, the mask layer 190 may include a conductive metal nitride (e.g., titanium nitride).

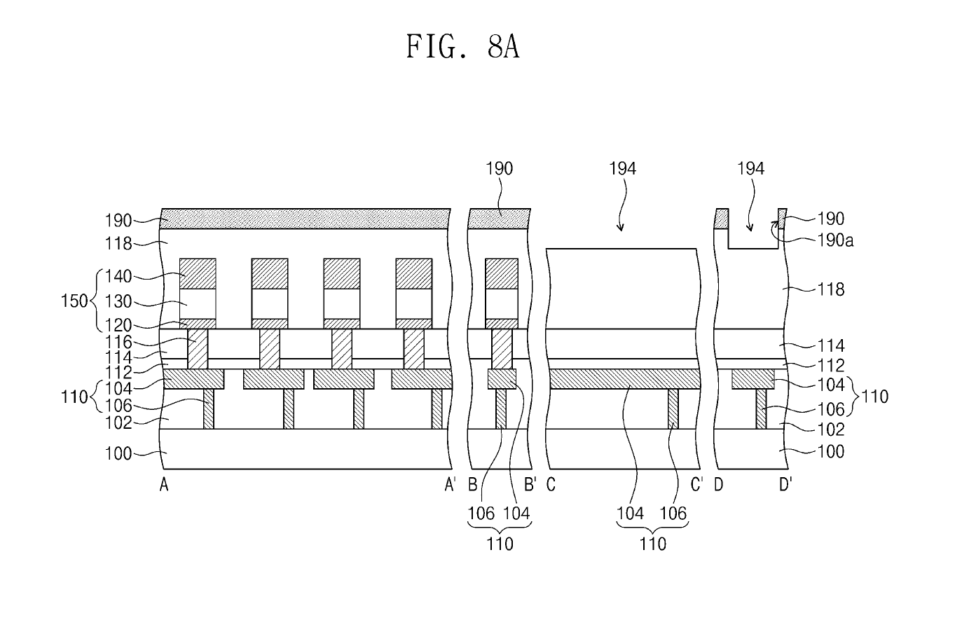

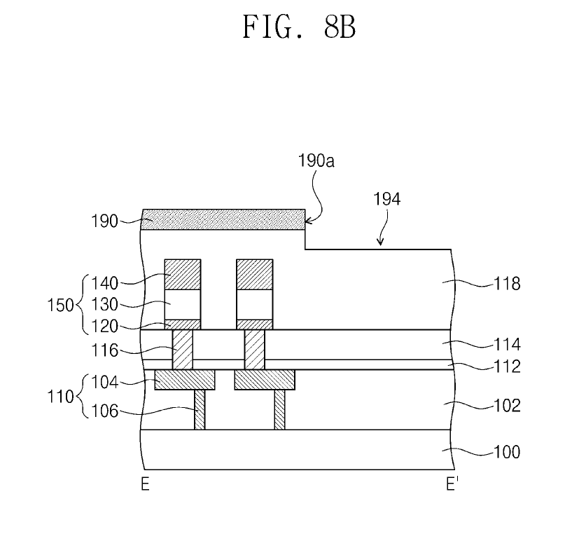

Referring to FIGS. 8A and 8B, at 503 in FIG. 5 the mask layer 190 on the peripheral circuit region PR may be patterned to form a first opening 190a in the mask layer 190. The first opening 190a may expose the mold layer 118 on the peripheral circuit region PR. As viewed in a plan view, the first opening 190a may define a region where the first conductive line 180 of FIG. 1 is formed and a region where the second part P2 of the second conductive line 182 of FIG. 2 is formed. The mold layer 118 may be etched using the mask layer 190 (including the first opening 190a) as an etch mask to form a preliminary trench 194 in the mold layer 118.

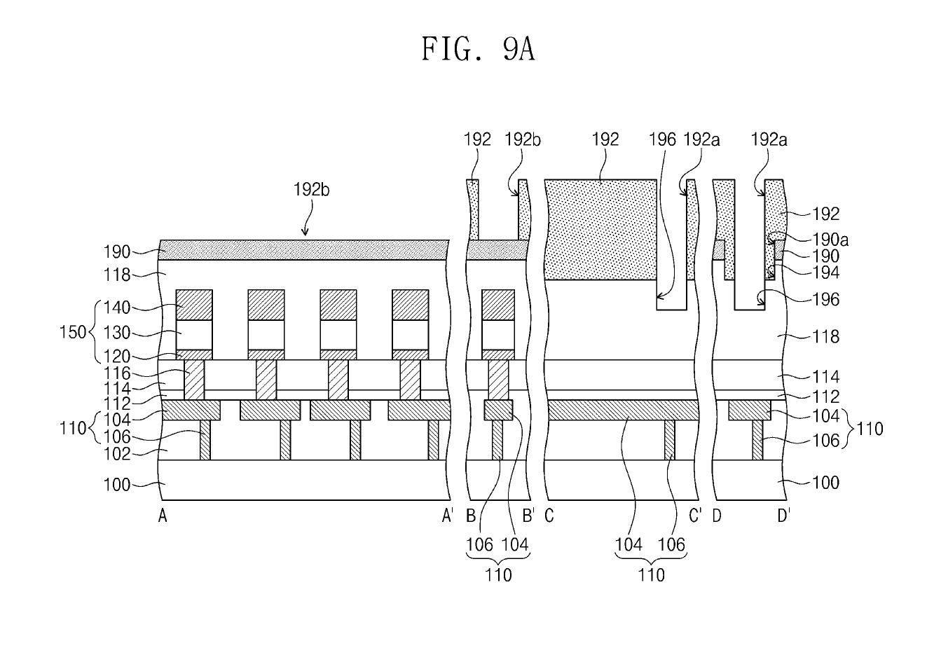

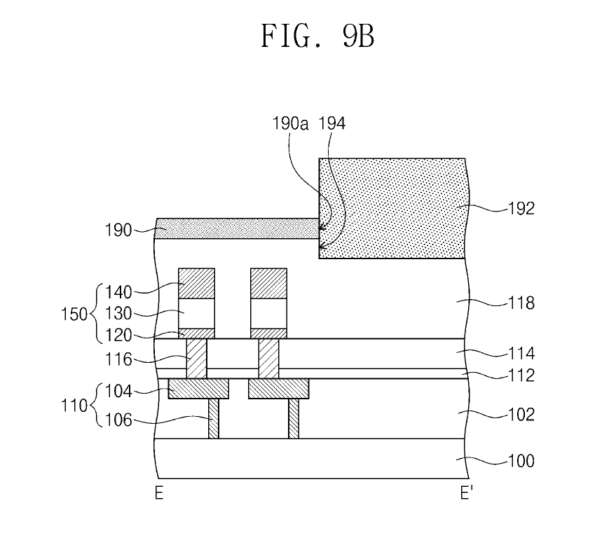

Referring to FIGS. 9A and 9B, at 504 in FIG. 5, a preliminary mask pattern 192 may be formed on the mask layer 190 that includes the first opening 190a formed in the mask layer 190. The preliminary mask pattern 192 may cover the cell region CR and the peripheral circuit region PR. The preliminary mask pattern 192 may partially fill the preliminary trench 194 that is formed on the peripheral circuit region PR and may include a first preliminary opening 192a partially exposing a bottom surface of the preliminary trench 194. As viewed in a plan view, the first preliminary opening 192a may define a region where the peripheral contact plug 170 of FIG. 1 is formed. The preliminary mask pattern 192 may further include a second preliminary opening 192b that exposes the mask layer 190 on the cell region CR. As viewed in a plan view, the second preliminary opening 192b may define a region where the second conductive line 182 of FIG. 1 is formed and a region where the first part P1 of the second conductive line 182 of FIG. 2 is formed. The preliminary mask pattern 192 may include, for example, a spin-on hardmask (SOH) material.

The mold layer 118 on the peripheral circuit region PR may be etched using the preliminary mask pattern 192 as an etch mask to form, in the mold layer 118, a preliminary hole 196 that extends from the bottom surface of the preliminary trench 194. The formation of the preliminary hole 196 may include etching the mold layer 118 that is exposed through the first preliminary opening 192a by performing an etch process that uses the preliminary mask pattern 192 as an etch mask and has an etch selectivity with respect to the mask layer 190. Therefore, the mask layer 190 exposed through the second preliminary opening 192b may not be removed on the cell region CR, but may remain on the mold layer 118 during the etch process to form the preliminary hole 196.

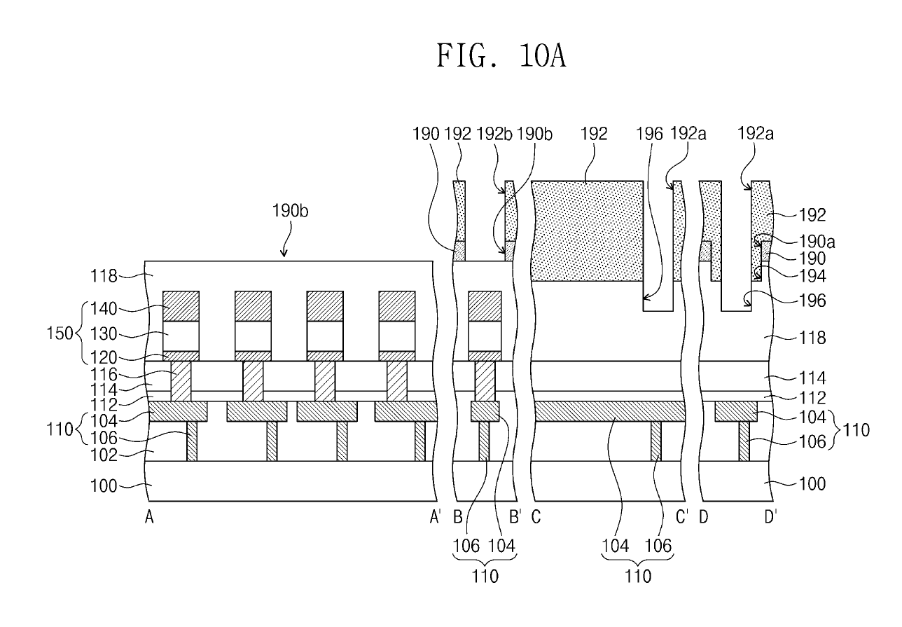

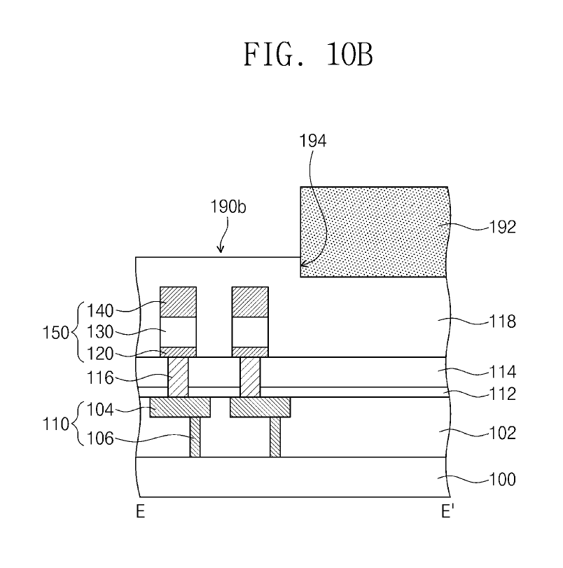

Referring to FIGS. 10A and 10B, at 505 in FIG. 5, the mask layer 190 on the cell region CR may be patterned using the preliminary mask pattern 192 as an etch mask to form a second opening 190b in the mask layer 190. The formation of the second opening 190b may include etching the mask layer 190 that is exposed through the second preliminary opening 192b by performing an etch process that uses the preliminary mask pattern 192 as an etch mask and has an etch selectivity with respect to the mold layer 118. As viewed in a plan view, the second opening 192b may define a region where the second conductive line 182 of FIG. 1 is formed and a region where the first part P1 of the second conductive line 182 of FIG. 2 is formed.

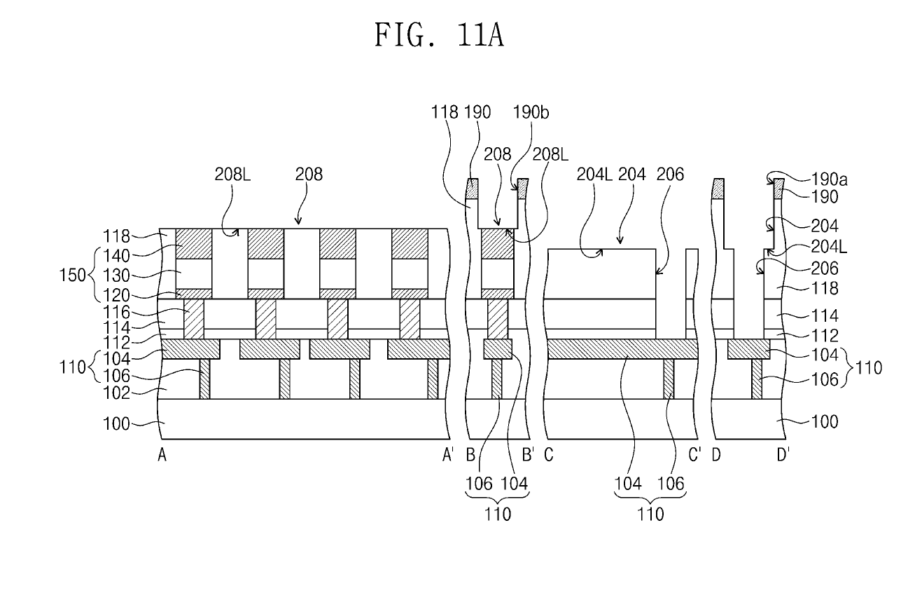

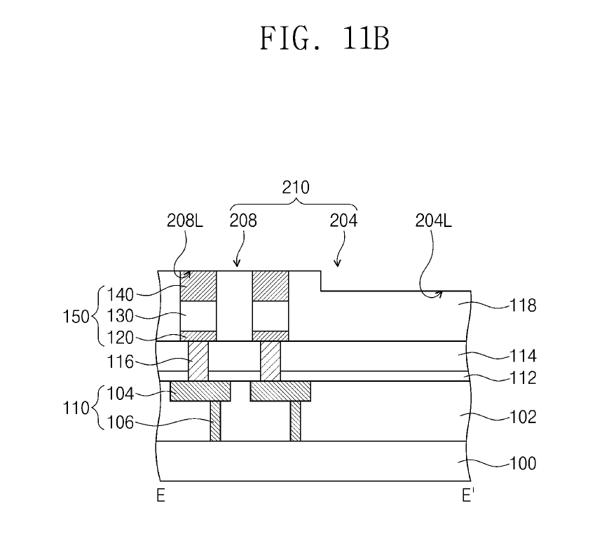

Referring to FIGS. 11A and 11B, at 506 in FIG. 5, the preliminary mask pattern 192 may be removed. The preliminary mask pattern 192 may be removed by performing, for example, an ashing process and/or a stripping process. After the preliminary mask pattern 192 has been removed, the mask layer 190 having the first and second openings 190a and 190b may remain on the mold layer 118. The mold layer 118 may be etched using the mask layer 190 having the first and second openings 190a and 190b as an etch mask to form, in the mold layer 180, a first trench 204 extending from the preliminary trench 194 toward the substrate 100, a peripheral contact hole 206 extending from the preliminary hole 196 toward the substrate 100, and a second trench 208 exposing the data storage structures 150. The first trench 204 may have a bottom surface 204L having a position from the substrate 100 that is lower than that of a bottom surface 208L of the second trench 208. The peripheral contact hole 206 may penetrate the mold layer 118, the second interlayer dielectric layer 114, and the intermediate layer 112 and thus expose a top surface of a corresponding one of the lines 104. The second trench 208 may expose top surfaces of the data storage structures 150 that are arranged in the first direction D1, as discussed with reference to FIG. 1. In the case in which the second conductive line 182 extends toward the peripheral circuit region PR from the cell region CR, as discussed with reference to FIG. 2, the second trench 208 and the first trench 204 may be connected to each other to form a single trench 210 as depicted in FIG. 10B. In this case, as the first trench 204 has the bottom surface 204L that has a position from the substrate 100 that is lower than that of the bottom surface 208L of the second trench 208, the trench 210 may have a bottom surface that has a profile that is stepped at an interface between the cell region CR and the peripheral circuit region PR.

Referring back to FIGS. 3 and 4, a first conductive line 180, a peripheral contact plug 170, and a second conductive line 182 may respectively be formed in the first trench 204, the peripheral contact hole 206, and the second trench 208. The first conductive line 180 may include a first line pattern 164 and a first barrier pattern 166 that extends along sidewalls and a bottom surface of the first line pattern 164. The peripheral contact plug 170 and the first line pattern 164 may be in contact with each other to form a single unitary body, and the first barrier pattern 166 may extend from the bottom surface of the first line pattern 164 toward sidewalls and a bottom surface of the peripheral contact plug 170. The second conductive line 182 may include a second line pattern 160 and a second barrier pattern 162 that extends along sidewalls and a bottom surface of the second line pattern 160. The formation of the first conductive line 180, the peripheral contact plug 170, and the second conductive line 182 may include forming, on the mold layer 118, a barrier layer that covers inner walls of the first trench 204, the peripheral contact hole 206, and the second trench 208. A conductive layer may be formed on the barrier layer that fills the first trench 204, the peripheral contact hole 206, and the second trench 208. The conductive and barrier layers may be planarized until the mold layer 118 is exposed. Therefore, the first line pattern 164 and the peripheral contact plug 170 may be locally formed in the first trench 204 and the peripheral contact hole 206. The first barrier pattern 166 may be interposed between the first line pattern 164 and the mold layer 118, between the peripheral contact plug 170 and the mold layer 118, between the peripheral contact plug 170 and the second interlayer dielectric layer 114, and between the peripheral contact plug 170 and the intermediate layer 112. The first barrier pattern 166 may be further interposed between the bottom surface of the peripheral contact plug 170 and the corresponding line 104 connected to the peripheral contact plug 170. Through the planarization process, the second line pattern 160 may be locally formed in the second trench 208, and the second barrier pattern 162 may be interposed between the second line pattern 160 and the mold layer 118. The second barrier pattern 162 may be further interposed between the second line pattern 160 and each of the data storage structures 150 arranged in the first direction D1.

Through the planarization process, the first and second conductive lines 180 and 182 may respectively have top surfaces 180U and 182U positioned at substantially the same height from the substrate 100. The first trench 204 may have the bottom surface 204L having a position from the substrate 100 that is lower than a position of the bottom surface 208L of the second trench 208 so that the first conductive line 180 may have a bottom surface 180L having a position from the substrate 100 that is lower than a position of a bottom surface 182L of the second conductive line 182.

As shown in FIGS. 2 and 4, in a case in which the second conductive line 182 extends from the cell region CR toward the peripheral circuit region PR, the second conductive line 182 may be formed in the trench 210 that is created through connection of the first and second trenches 204 and 208 to each other. In this case, the second conductive line 182 may include a first part P1 that is formed in the first trench 204 and a second part P2 that is formed in the second trench 208. Through the planarization process, the first and second parts P1 and P2 may respectively have top surfaces P1_U and P2_U that are positioned at the substantially same height from the substrate 100. The first trench 204 may have the bottom surface 204L that has a position from the substrate 100 that is lower than a position of the bottom surface 208L of the second trench 208 so that the first part P1 may have a bottom surface P1_L that has a position from the substrate 100 is lower than a position of a bottom surface P2_L of the second part P2. In this case, the second conductive line 182 may have a bottom surface that has a profile that is stepped at an interface between the first part P1 and the second part P2.

According to the present inventive concept, the preliminary trench 194 and the preliminary hole 196 may be formed in the mold layer 118 on the peripheral circuit region PR. As viewed in a plan view, the preliminary trench 194 and the preliminary hole 196 may define regions where the first conductive line 180 and the peripheral contact plug 170 are formed. Thereafter, it may be possible to simultaneously form the first trench 204 that extends from the preliminary trench 194 toward the substrate 100, the peripheral contact hole 206 that extends from the preliminary hole 196 toward the substrate 100, and the second trench 208 that exposes the data storage structures 150 on the cell region CR. As the preliminary trench 194 and the preliminary hole 196 are formed in the mold layer 118 before the first trench 204 and the peripheral contact hole 206 are formed, the peripheral contact hole 206 may be formed to have a relatively low aspect ratio. It thus may be possible to easily form the peripheral contact hole 206, and it may not be necessary for any additional contact (or pad) for the electrical connection to be between the first conductive line 180 and a corresponding line 104. As a result, it may be advantageous to simplify the fabrication process of the data storage device and to prevent the occurrence of defects that may be caused by the formation of the additional contact (or pad).

It may then be possible to easily fabricate the data storage device having superior reliability.

According to the present inventive concept, the first conductive line may have the bottom surface having a position from the substrate that is lower than a position of the bottom surface of the second conductive line. Therefore, it may be possible that the peripheral contact plug is formed to have a relatively low aspect ratio for the electrical connection between the first conductive line and its underlying line. In addition, it may not be necessary for any additional contact (or pad) for the electrical connection between the first conductive line and the underlying line. As a result, it may be advantageous to simplify the fabrication process of the data storage device and to prevent the occurrence of defects that may be caused by the formation of an additional contact (or pad).

It therefore may be provided the data storage device and a method for fabricating the same having a superior reliability and easy fabrication.

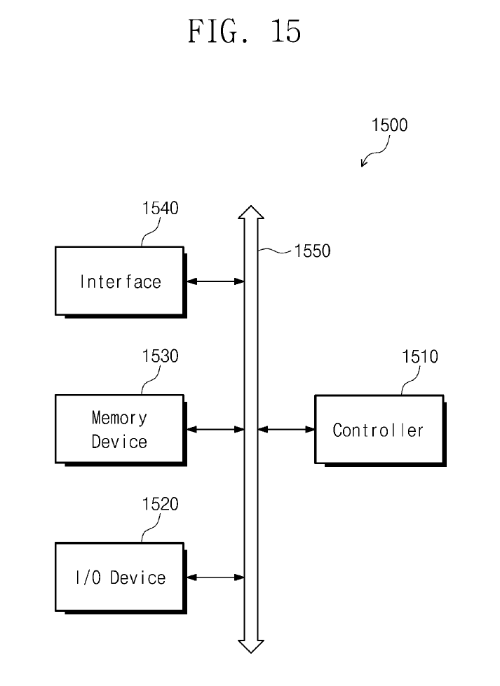

FIG. 15 depicts an electronic device 1500 that comprises one or more integrated circuits (chips) comprising a semiconductor device that includes a data storage device according to embodiments disclosed herein. Electronic device 1500 may be used in, but not limited to, a computing device, a personal digital assistant (PDA), a laptop computer, a mobile computer, a web tablet, a wireless phone, a cell phone, a smart phone, a digital music player, or a wireline or wireless electronic device. The electronic device 1500 may comprise a controller 1510, an input/output device 1520 such as, but not limited to, a keypad, a keyboard, a display, or a touch-screen display, a memory 1530, and a wireless interface 1540 that are coupled to each other through a bus 1550. The controller 1510 may comprise, for example, at least one microprocessor, at least one digital signal process, at least one microcontroller, or the like. The memory 1530 may be configured to store a command code to be used by the controller 1510 or a user data. Electronic device 1500 and the various system components comprising a semiconductor device that includes a data storage device according to embodiments disclosed herein. The electronic device 1500 may use a wireless interface 1540 configured to transmit data to or receive data from a wireless communication network using a RF signal. The wireless interface 1540 may include, for example, an antenna, a wireless transceiver and so on. The electronic system 1500 may be used in a communication interface protocol of a communication system, such as, but not limited to, Code Division Multiple Access (CDMA), Global System for Mobile Communications (GSM), North American Digital Communications (NADC), Extended Time Division Multiple Access (E-TDMA), Wideband CDMA (WCDMA), CDMA2000, Wi-Fi, Municipal Wi-Fi (Muni Wi-Fi), Bluetooth, Digital Enhanced Cordless Telecommunications (DECT), Wireless Universal Serial Bus (Wireless USB), Fast low-latency access with seamless handoff Orthogonal Frequency Division Multiplexing (Flash-OFDM), IEEE 802.20, General Packet Radio Service (GPRS), iBurst, Wireless Broadband (WiBro), WiMAX, WiMAX-Advanced, Universal Mobile Telecommunication Service-Time Division Duplex (UMTS-TDD), High Speed Packet Access (HSPA), Evolution Data Optimized (EVDO), Long Term Evolution-Advanced (LTE-Advanced), Multichannel Multipoint Distribution Service (MMDS), and so forth.

Although the present invention has been described in connection with the embodiment of the present invention illustrated in the accompanying drawings, it is not limited thereto. It will be apparent to those skilled in the art that various substitution, modifications and changes may be thereto without departing from the scope of the attached claims.

1. A data storage device, comprising:
a substrate including a cell region and a peripheral circuit region;
a first conductive line on the peripheral circuit region of the substrate;
a peripheral contact plug between the substrate and the first conductive line, the peripheral contact plug being in contact with the first conductive line;
a second conductive line on the cell region of the substrate;
a plurality of data storage structures between the substrate and the second conductive line, the plurality of data storage structures connecting to the second conductive line; and
a wiring structure between the substrate and each of the data storage structures and between the substrate and the peripheral contact plug,
wherein the first conductive line includes a bottom surface having a position from the substrate that is lower than a position of a bottom surface of the second conductive line.

2. The data storage device of claim 1, wherein the first conductive line further includes a top surface having a position from the substrate is substantially the same as a position of a top surface of the second conductive line.

3. The data storage device of claim 1, further comprising a plurality of cell contact plugs between the wiring structure and each of the data storage structures, the cell contact plugs respectively connecting to the data storage structures,
wherein the wiring structure comprises lines spaced apart from the substrate, and
wherein each of the cell and peripheral contact plugs is connected to a corresponding one of the lines.

4. The data storage device of claim 3, wherein the lines of the wiring structure comprises a metallic material.

5. The data storage device of claim 1, wherein
the first conductive line comprises a first line pattern and a first barrier pattern that extends along sidewalls and a bottom surface of the first line pattern,
the second conductive line comprises a second line pattern and a second barrier pattern that extends along sidewalls and a bottom surface of the second line pattern,
the peripheral contact plug and the first line pattern are in contact with each other to form a single unitary body, and
the first barrier pattern extends along sidewalls and a bottom surface of the peripheral contact plug from the bottom surface of the first line pattern.

6. The data storage device of claim 5, wherein
the first line pattern, the second line pattern, and the peripheral contact plug comprise a same material, and
the first barrier pattern and the second barrier pattern comprise a same material.

7. A method for manufacturing a data storage device, the method comprising:
providing a substrate including a cell region and a peripheral circuit region;
forming a plurality of data storage structures on the cell region of the substrate;
forming a mold layer that covers the data storage structures and extends onto the peripheral circuit region on the substrate;
forming a mask layer that covers the cell region and the peripheral circuit region on the mold layer;
forming a first opening in the mask layer, the first opening exposing the mold layer formed on the peripheral circuit region;
etching the mold layer using the mask layer having the first opening as an etch mask to form a preliminary trench in the mold layer formed on the peripheral circuit region;
forming a second opening in the mask layer, the second opening exposing the mold layer formed on the cell region; and
etching the mold layer using the mask layer having the first and second openings as an etch mask to form a first trench extending from the preliminary trench toward the substrate and a second trench exposing the data storage structures.

8. The method of claim 7, wherein the first trench comprises a bottom surface having a position from the substrate is lower than a position of a bottom surface of the second trench.

9. The method of claim 7, further comprising:
forming a preliminary hole extending from a bottom surface of the preliminary trench toward the substrate; and
etching the mold layer using the mask layer having the first and second openings as an etch mask to form a peripheral contact hole extending from the preliminary hole toward the substrate.

10. The method of claim 9, further comprising forming a wiring structure between the substrate and each of the data storage structures and between the mold layer and the substrate,
wherein the wiring structure comprises a plurality of lines spaced apart from the substrate, and
wherein the peripheral contact hole exposes a corresponding one of the lines.

11-15. (canceled)

16. A data storage device, comprising:
a substrate comprising a cell region and a peripheral circuit region;
a mold layer on the cell region and the peripheral circuit region;
a first conductive line on the mold layer in the cell region, a bottom surface of the first conductive line being at a first height above the substrate;
a plurality of data storage structures in contact with the first conductive line, the plurality of data storage structures being disposed between the substrate and the first conductive line;
a second conductive line on the mold layer in the peripheral circuit region, a bottom surface of the second conductive line being at a second height above the substrate, the second height being less that the first height; and
a peripheral contact plug in contact with the second conductive line and being disposed between the substrate and the second conductive line.

17. The data storage device of claim 16, wherein the first conductive line extends in a first direction and comprises a width in a second direction, the second width being substantially perpendicular to the first direction, and
wherein the second conductive line extends in the first direction and comprises a width in the second direction that is greater than the width of the first conductive line.

18. The data storage device of claim 17, wherein the peripheral contact plug comprises a width in the second direction, the width of the peripheral contact plug being less than the width of the second conductive line.

19. The data storage device of claim 16, wherein the first conductive line includes a first barrier layer on sidewall surfaces and the bottom surface of the first conductive line, and
wherein the second conductive line includes a second barrier layer on sidewall surfaces and the bottom surface of the second conductive line.

20. The data storage device of claim 19, wherein the first conductive line and the second conductive line comprise a same conductive material.

21. The data storage device of claim 20, wherein the first barrier layer and the second barrier layer comprise a same material.

22. The data storage device of claim 16, further comprising a first wiring structure between at least one of the plurality of data storage structures and the substrate, the at least one data storage structure being electrically connected to the first wiring structure.

23. The data storage device of claim 22, further comprising a second wiring structure between the peripheral contact plug and the substrate, the peripheral contact plug being electrically connected to the second wiring structure.

24. The data storage device of claim 16, further comprising a wiring structure between the peripheral contact plug and the substrate, the peripheral contact plug being electrically connected to the wiring structure.

25. The data storage device of claim 16, wherein the plurality of data storage structures comprise magnetic tunnel junction devices. 26-35. (cancelled)
